(19) United States
(12) Patent Application Publication
(10) Pub. No.: US 2025/0307484 A1
(43) Pub. Date: Oct. 2, 2025

(54) TERRAIN MODEL UPDATES FOR UAV SERVICE

(71) Applicant: WING AVIATION LLC, Mountain View, CA (US)

(72) Inventors: XINZHI FAN, San Mateo, CA (US); DINUKA ABEYWARDENA, Mountain View, CA (US); KONSTANTIN BOZHKOV, Santa Clara, CA (US); DOMITILLE COMMUN, Mountain View, CA (US)

(21) Appl. No.: 18/624,733

(22) Filed: Apr. 2, 2024

(51) Int. Cl. G06F 30/13

(52) U.S. Cl. CPC G06F 30/13

(57) ABSTRACT

A technique for maintaining a backend terrain model used by a fleet of unmanned aerial vehicles (UAVs) of a UAV service supplier (USS) includes acquiring sensor data of a terrain below a first UAV of the fleet of UAVs as the first UAV executes a mission. The sensor data is analyzed with a terrain detection module disposed on-board the first UAV to determine whether the terrain deviates from a local terrain model describing the terrain. The local terrain model is stored on-board the first UAV. A terrain deviation message is issued from the first UAV to a backend management system of the USS that maintains the backend terrain model in response to a determination that the terrain deviates from the local terrain model. The terrain deviation message includes an indication that a deviant terrain has been identified and location data indicating an approximate location of the deviant terrain.

### TECHNICAL FIELD

This disclosure relates generally, though not exclusively, to maintaining terrain models used for navigation by unmanned aerial vehicles (UAVs) of a UAV service supplier.

### BACKGROUND INFORMATION

An unmanned vehicle, which may also be referred to as an autonomous vehicle, is a vehicle capable of traveling without a physically present human operator. Various types of unmanned vehicles exist for various different environments. For instance, unmanned vehicles exist for operation in the air, on the ground, underwater, and in space. Unmanned vehicles also exist for hybrid operations in which multi-environment operation is possible. Unmanned vehicles may be provisioned to perform various different missions, including payload delivery, exploration/reconnaissance, imaging, public safety, surveillance, or otherwise. The mission definition will often dictate a type of specialized equipment and/or configuration of the unmanned vehicle.

Unmanned aerial vehicles (also referred to as drones) can be adapted for package delivery missions to provide an aerial delivery service. One type of unmanned aerial vehicle (UAV) is a vertical takeoff and landing (VTOL) UAV. VTOL UAVs are particularly well-suited for package delivery missions. The VTOL capability enables a UAV to takeoff and land within a small footprint thereby providing package pick-ups and deliveries almost anywhere. To safely deliver packages in a variety of environments (particularly populated urban/suburban environments), the UAV should be capable of effectively identifying and avoiding ground-based obstacles. The ability to acquire and maintain accurate, detailed, and up-to-date terrain models of the delivery destinations, routes, and surrounding environments can help facilitate safe and intelligent navigation over these terrains.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1 illustrates operation of an unmanned aerial vehicle (UAV) service supplier (USS) that delivers packages into a neighborhood, in accordance with an embodiment of the disclosure.

FIG. 2 illustrates components of a USS system responsible for maintenance of a backend terrain model used by UAVs for navigation, in accordance with an embodiment of the disclosure.

FIG. 3 is a functional block diagram illustrating a system for navigation of UAVs, in accordance with an embodiment of the disclosure.

FIGS. 4A & 4B include a flow chart illustrating a process for maintaining a backend terrain model used by UAVs of the USS, in accordance with an embodiment of the disclosure.

FIG. 5A is a perspective view illustration of a UAV configured for use in a UAV delivery system, in accordance with an embodiment of the disclosure.

FIG. 5B is an underside plan view illustration of the UAV configured for use in the UAV delivery system, in accordance with an embodiment of the disclosure.

### DETAILED DESCRIPTION

Embodiments of a system, apparatus, and method of operation for maintaining a terrain model used by a fleet of unmanned aerial vehicles (UAVs) of an UAV service supplier (USS) are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The ability to acquire and maintain accurate, detailed, and up-to-date terrain models of the delivery destinations, routes, and surrounding areas over which a USS operates helps facilitate safe and intelligent navigation. A USS, such as a UAV delivery service, should be able to quickly detect significant terrain changes, reconstruct terrain models on-demand, and promulgate terrain model updates fleetwide with minimal delay. An example situation where terrain changes need to be quickly detected and conveyed to the backend management system are construction sites that erect cranes. As UAV delivery services increase market penetration and expand fleets to meet the developing demand, the ability to upload mission data may become bottlenecked. This is particularly true for USS that rely primarily, or exclusively, on wireless communication interfaces (e.g., cellular LTE) to convey mission data. To address this challenge, the techniques described herein use local terrain models onboard the UAVs to detect terrain deviations, assess the significance of those changes and their own confidence in detecting a significant deviation, and inform the backend management system of any detected deviant terrain. The backend management system can then determine whether to solicit sensor data from the fleet related to the deviant terrain and perform an on-demand reconstruction of the backend terrain model. This on-demand solicitation of the sensor data (as opposed to unsolicited uploads) reduces the amount of mission data uploaded from the UAVs to the backend management system. The individual UAVs can provide their estimates of the significance of a terrain deviation based upon their individual experience, but the backend management system can make a more informed decision as to whether a terrain deviation is significant based upon multiple reports from across the fleet. This wholistic fleet perspective is better situated to access whether limited communication bandwidth should be dedicated to upload sensor data (e.g., aerial images) for reconstruction of the backend terrain model each time a deviation terrain is identified.

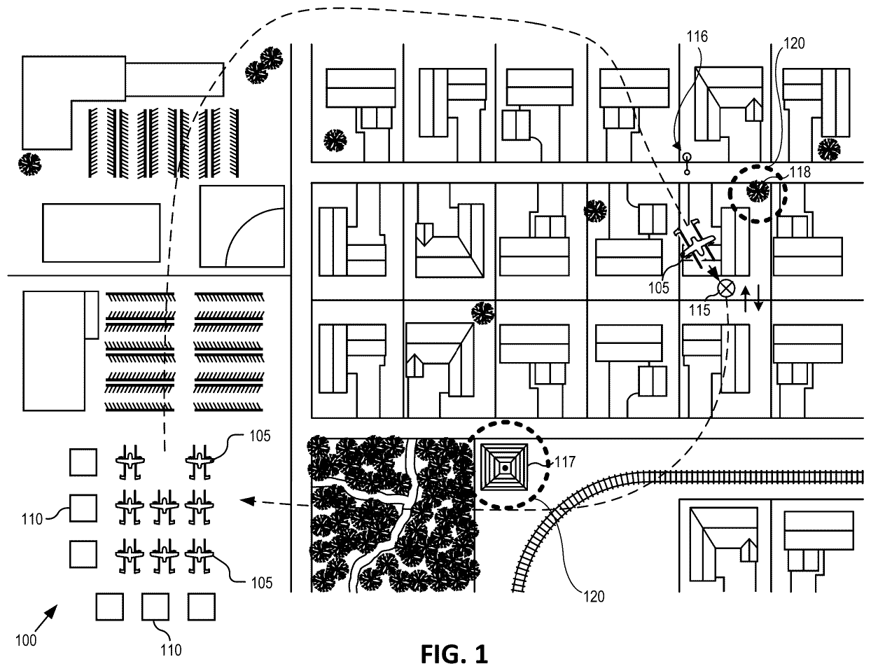

FIG. 1 illustrates operation of a USS, such as a UAV delivery service that delivers packages into a neighborhood, in accordance with an embodiment of the disclosure. UAVs may one day routinely deliver items into urban or suburban neighborhoods from small regional or neighborhood hubs such as terminal area 100 (also referred to as a local nest or staging area). Vendor facilities that wish to take advantage of the aerial delivery service may set up adjacent to terminal area 100 (such as vendor facilities 110) or be dispersed throughout the neighborhood for waypoint package pickups (not illustrated). An example aerial delivery mission may include multiple mission phases such as takeoff from terminal area 100 with a package for delivery to a destination area 115 (also referred to as a delivery zone, drop zone, or delivery destination), rising to a cruising altitude, and cruising to the customer destination. At destination area 115, UAV 105 descends for package drop-off before once again ascending to a cruise altitude for the return cruise back to terminal area 100.

During the course of a delivery mission, ground-based obstacles are an ever-present hazard—particularly tall slender obstacles such as streetlights 116, telephone poles, radio towers 117, cranes, trees 118, etc. Some of these obstacles may be persistent unchanging obstacles (e.g., streetlights, telephone poles, radio towers, etc.) while others may be temporary (cranes, etc.), or ever changing/growing (e.g., trees). Most of these obstacles may be mapped and included in the backend terrain model maintained by the backend management system of the USS. Occasionally, one of these obstacles may be newly erected into the environment (e.g., tower 117) or have sufficiently changed (e.g., growth of trees 118) such that their presence or changes substantially deviate from the current version of the backend terrain model maintained by the USS. In these scenarios, the deviant terrains 120 should be quickly identified, reported, and if necessary, the terrain model reconstructed and updates pushed out to the fleet.

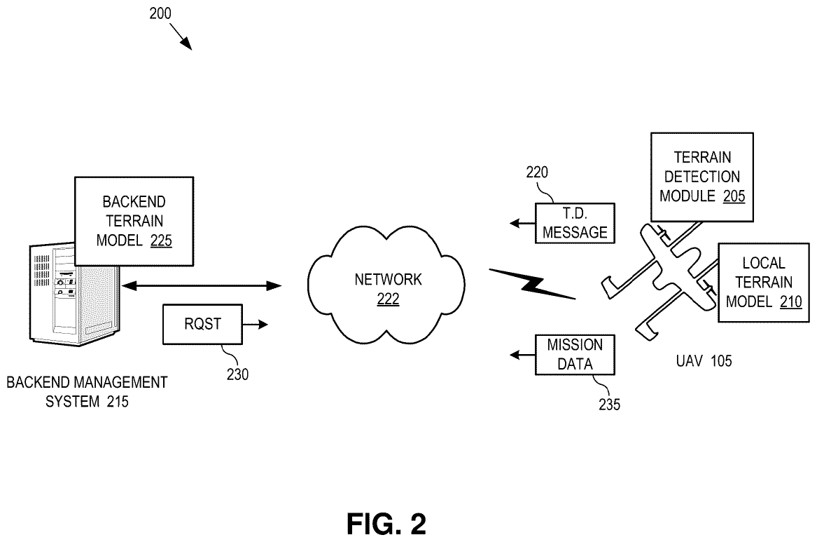

FIG. 2 illustrates components of a USS system 200 responsible for maintenance of a backend terrain model used by UAVs 105 for navigation, in accordance with an embodiment of the disclosure. As illustrated, UAVs 105 include a terrain detection module 205 and local terrain model 210 stored on-board the aircraft. Local terrain model 210 may be a digital surface model, point cloud, meshes, etc. that include a three-dimensional (3D) topographical representation of the earth's surface including objects thereon. In preparation of a given delivery mission, UAV 105 is provisioned by backend management system 215 with mission instructions that include delivery destination 115 along with the relevant local terrain model 210, if not already stored on-board. As UAV 105 executes its mission (e.g., delivery mission), it continually acquires sensor data of its surrounding environment, including aerial images of the terrain immediately below UAV 105, as part of its vision-based navigation and obstacle avoidance systems. The sensor data is analyzed by terrain detection module 205 and compared against local terrain model 210. If the terrain significantly deviates from local terrain model 210, then it is deemed to be a deviant terrain. A significant deviation may be determined using thresholds, which thresholds may be dynamic based upon land use classifications, activity classifications (e.g., is the area a known active construction site), or otherwise.

Once a specific area or terrain is deemed to be a deviant terrain, UAV 105 issues a terrain deviation message 220 to backend management system 215. In one embodiment, terrain deviation message 220 is transmitted wirelessly over network 222 (e.g., cellular LTE network) to backend management system 215. In one embodiment, terrain deviation message 220 is issued immediately by UAV 105 without delay while its mission is still underway. Terrain deviation message 220 includes at least an indication that a deviant terrain has been identified (e.g., deviant terrain flag asserted) and an approximately location (e.g., GNSS coordinates, etc.) of the deviation terrain. In various embodiments, terrain deviation message 220 may further include a confidence score and a significance score as well. In response, backend management system 215 uses terrain deviation message 220 (along with any other relevant terrain deviation messages it may have received from other UAVs), to determine whether to update its backend terrain model 225. In one embodiment, backend terrain model 225 may be considered a master terrain model maintained by the USS and from which local terrain models 210 are derived. In other words, local terrain models 210 may be snippets exported from backend terrain model 225 and provisioned into UAVs 105 with mission instructions. If backend management system 215 decides a reconstruction of backend terrain model 225 is advisable, then a request 230 is issued soliciting sensor data (e.g., aerial images) of the deviant terrain. Request 230 may be a one-to-one request sent solely to a specific UAV 105 or a one-to-many group request sent to multiple UAVs 105 to crowdsource additional sensor data across the fleet. In response to request 230, UAV 105 uploads mission data 235, which includes its sensor data of the specific deviant terrain 120.

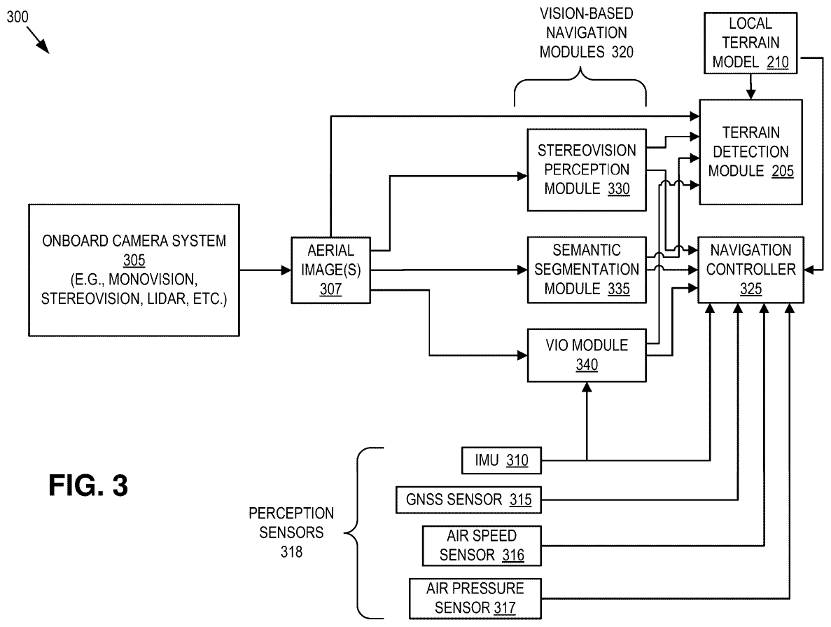

FIG. 3 is a functional block diagram illustrating a system 300 disposed onboard UAVs 105 for vision-based navigation and validation of local terrain models 210, in accordance with an embodiment of the disclosure. The illustrated embodiment of system 300 includes an onboard camera system 305 for acquiring aerial images 307, an inertial measurement unit (IMU) 310, a global navigation satellite system (GNSS) sensor 315, an air speed sensor 316 (e.g., pitot tube), an air pressure sensor 317 (e.g., barometer), visual tracking modules 320, and a navigation controller 325, as well as, terrain detection module 205 and local terrain model 210. Collectively, the sensors 310-317 are referred to as perception sensors 318. The illustrated embodiment of visual tracking modules 320 includes a stereovision perception module 330, a semantic segmentation module 335, and a visual inertial odometry (VIO) module 340.

Onboard camera system 305 is disposed on UAVs 105 with a downward looking position to acquire aerial images 307. Aerial images 307 may be acquired at a regular video frame rate (e.g., 20 f/s, 30 f/s, etc.) and a subset of the images provided to the various visual tracking modules 320 for analysis. Onboard camera system 305 may be implemented as a monovision camera system, a stereovision camera system, a laser imaging, detection, and ranging (LIDAR) camera system, an infrared sensor, a combination of these systems, or otherwise. As such, aerial images 307 may be monochromatic or color images, stereovision images, lidar images, infrared images, or otherwise. While capturing aerial images 307, the camera intrinsics along with sensor readings from the onboard perception sensors may be recorded and indexed to aerial images 307. For example, IMU 310 may include one or more of an accelerometer, a gyroscope, or a magnetometer to capture accelerations (linear or rotational), attitude, and heading readings. GNSS sensor 315 may be a global positioning system (GPS) sensor, or otherwise, and output longitude/latitude position, mean sea level (MSL) altitude, heading, speed over ground (SOG), etc. Air speed sensor 316 captures air speed of UAV 105 while underway, which may serve as a rough approximation for SOG when adjusted for weather conditions. Barometer 317 measures air pressure, which provides MSL altitude, which may be offset using elevation map data to estimate above ground level (AGL) altitude. Aerial images 307 and/or the outputs of perception sensors 318 are generically referred to herein as sensor data.

During flight missions, visual tracking modules 320 are operated as part of the onboard machine vision system and may constantly receive aerial images 307 and identify objects represented in those aerial images. Stereovision perception module 330 analyzes parallax between stereovision aerial images acquired by onboard camera system 305 to estimate distance to pixels/features/objects in aerial images 307. These stereovision depth estimates may be referred to as a stereovision depth map. VIO module 340 estimates the three-dimensional (3D) pose (e.g., position/orientation) of onboard camera system 305 of UAV 105 using aerial images 307 and IMU 310. In other words, VIO module 304 provides ego-motion tracking relative to the surrounding environment of UAV 105. Semantic segmentation module 335 uses image segmentation to inform object detection/identification and feature tracking within aerial images 307. Feature tracking includes the identification and tracking of features within aerial images 307. Features may include edges, corners, high contrast points, etc. of objects within aerial images 307. Recognized objects may be tracked and the identifications provided to other modules responsible for making real-time flight decisions. Vision-based navigation modules 320 may also include other vision perception modules (not illustrated) such as a lidar analysis module or an optical flow analysis module to extract distance/depth information from aerial images 307. Collectively, visual tracking modules 320 provide vision-based analysis and understanding of the surrounding environment, which may be used by navigation controller 325 to inform navigation decisions and perform localization, automated obstacle avoidance, route traversal, etc. Of course, the output from the visual tracking modules 320 may be combined with, or considered in connection with, other real-time sensor data from IMU 310, GNSS sensor 315, airspeed sensor 316, and air pressure sensor 317 by navigation controller 325 to make more fully informed navigation decisions.

Additionally, terrain detection module 205 may analyze the various sensor data (including derivatives therefrom) to determine the relative distance, location, or orientation of UAV 105 relative to the ground and objects perceived in its immediate environment. This environmental sensing can then be compared by terrain detection module 205 against local terrain model 210 to determine what objects or ground surface contours UAV 105 should expect to sense relative to its current position. Though not illustrated so as not to clutter the drawings, terrain detection module 205 may also have access to sensor data from perception sensors 318 (e.g., GNSS sensor data) so that it can determine the current position of UAV 105 and compare current sensor data against the appropriate portions of local terrain model 210.

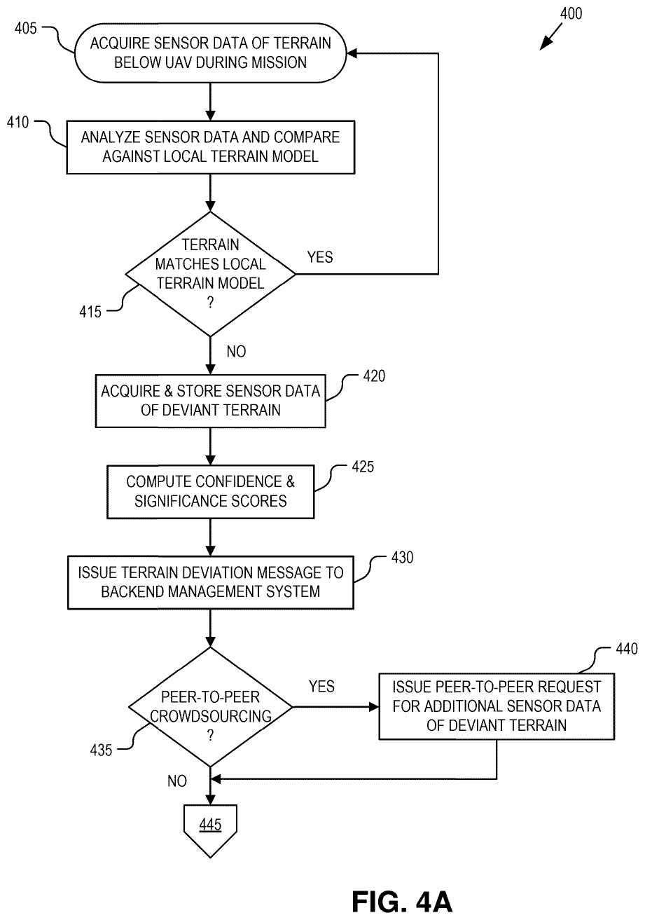

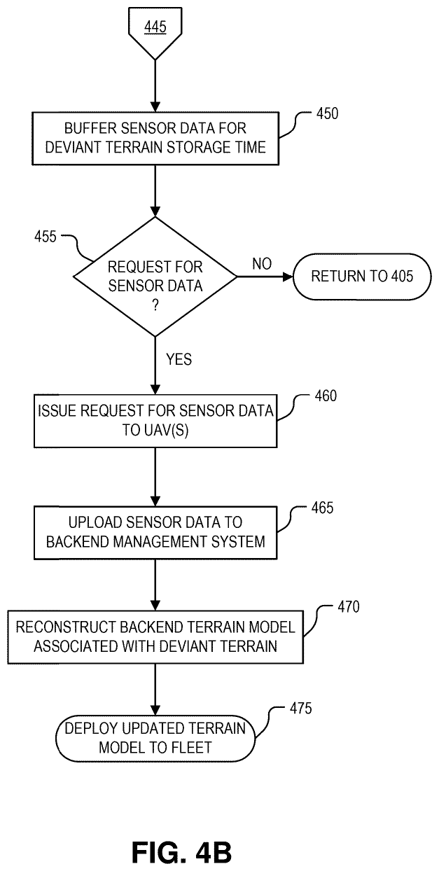

FIGS. 4A & 4B are a flow chart illustrating a process 400 for maintaining backend terrain model 225 provisioned into UAVs 105 of the USS, in accordance with an embodiment of the disclosure. The order in which some or all of the process blocks appear in process 400 should not be deemed limiting. Rather, one of ordinary skill in the art having the benefit of the present disclosure will understand that some of the process blocks may be executed in a variety of orders not illustrated, or even in parallel.

In a process block 405, UAV 105 acquires sensor data of a terrain below the aircraft as UAV 105 executes a mission (e.g., delivery mission). The sensor data includes aerial images 307, but may also include sensor data from one or more of perception sensors 318. Upon acquiring the sensor data, the data from perception sensors 318 may be indexed with aerial images 307 and buffered on-board UAV 105 for analysis and potential future upload to backend management system 215 as part of a mission log upload.

In a process block 410, terrain detection module 205 analyzes the sensor data to determine whether the terrain below UAV 105 deviates from local terrain model 210. In one embodiment, this analysis includes terrain detection model 205 using GNSS sensor data (e.g., GPS coordinates) to access local terrain model 210 and determine the corresponding portion of local terrain model 210 that should be compared against the sensor data indicative of the surface topology immediately below UAV 105. For example, terrain detection module 205 may rely upon analysis of aerial images 307 provided by vision-based navigation modules 320 to generate a real-time surface topology that is compared against the expected surface topology provided in local terrain model 210. As mentioned above, the surface topology includes both earth's surface and objects/structures (natural or manmade) disposed thereon.

In a decision block 415, terrain detection module 205 makes a determination as to whether the terrain deviates from local terrain model 210. In one embodiment, this determination may be based upon the terrain deviation exceeding a specified threshold magnitude. For example, the terrain detection module 205 may be programmed to only analyze a near field distance extending out a fixed distance (e.g., 15 or 20 meters) from UAV 105. If onboard sensors identify an object (e.g., ground or other obstacle) within this near-field distance, then terrain detection module 205 may reference local terrain model 210 to determine if this object is expected based upon the current knowledge of the environment stored in local terrain model 210. The threshold deviation may then be applied to only trigger an alert or assert a terrain deviation flag if the discrepancy exceeds the specified threshold (e.g., object was more than 1 or 2 m closer than expected based upon local terrain model 210).

In some embodiments, the threshold magnitude may be dynamic. For example, the threshold magnitude may be increased or decreased based upon one or more classifications of the ground area. These classifications may include land use classifications (e.g., urban, commercial, industrial, residential, rural, agricultural, or other zoning or density classifications). In yet another embodiment, the classifications may include an activity classification based upon a knowledge graph of the neighborhood or area. An example activity classification may include a known construction site that may have an increased likelihood for erection/movement of cranes.

If a threshold is exceeded and a deviant terrain identified (decision block 415), then process 400 continues to a process block 420. In process block 420, sensor data (including aerial images 307, outputs/analysis of vision-based navigation modules 320, perception sensors 318, etc.) are stored and collectively indexed in local memory on-board UAV 105. The stored analysis, which may be included as part of the saved sensor data may include at least one of a stereovision depth analysis of aerial images 307, an optical flow analysis of aerial images 307, a semantic segmentation analysis of aerial images 307, a light detection and ranging analysis, or otherwise. The sensor data along with real-time analysis may be captured and stored within a mission log. In one embodiment, the storage time that the mission log, or specific sensor data associated with a terrain deviation, is stored may be increased relative to storage times associated with non-deviant terrains. For example, the storage time associated with a deviant terrain may be stored for a period of time that exceeds a duration of the current mission (e.g., 24 hours, 48 hours, 72 hours, a week, etc.). The extended storage time provides backend management system 215 an extended period of time to determine whether it should solicit the sensor data and reconstruct backend terrain model 225 while acquiring additional sensor data from other sources or other UAVs 105 within the fleet.

In one embodiment, UAV 105 may acquire and/or store sensor data associated with deviant terrain with greater resolution, frame rate, fidelity, or voluminosity than other sensor data associated with non-deviant terrain. For example, upon identification of a deviant terrain, UAV 105 may loiter longer over the deviant terrain, circle the deviant terrain, or perform an extra flyby over the deviant terrain to increase the quality or amount of the sensor data captured and stored in connection with the deviant terrain.

In a process 425, upon detection of a deviant terrain, terrain detection module 205 may also compute a confidence score indicating its level of confidence that the terrain does indeed deviate from local terrain model 210. This confidence score may be based upon the magnitude of the deviation, the obliqueness of the aerial images 307 to the deviant terrain, image quality, etc. Additionally (or alternatively), terrain detection module 205 generates a significance score indicating a perceived level of importance or hazard associated with the deviant terrain. Again, importance/hazard may be based upon the position, orientation, or height of the deviant terrain. In one embodiment, terrain detection module 205 is itself a neural network trained to identify terrain deviations with the sensor data and local terrain model 210 provided as inputs to the neural network. The neural network may also be trained to provide confidence and significance scores as outputs along with the determination of deviant or non-deviant terrain.

Once a deviant terrain has been identified, UAV 105 issues a terrain deviation message 220 to backend management system 215. Terrain deviation message 220 includes an indication that a deviant terrain has been identified (e.g., asserting a deviant terrain flag) along with location data indicating an approximate location of the deviant terrain. In one embodiment, location data includes a GNSS location. In another embodiment, the location data includes coordinates that reference the local or backend terrain models. The terrain deviation message 220 may also include the confidence and significance scores, if computed.

In some embodiments, peer-to-peer crowdsourcing of additional sensor data of the presumptive deviant terrain may be performed (decision block 435). Peer-to-peer crowdsourcing may be performed between UAVs 105 staged at a common local nest or terminal area 100. A UAV 105 that has identified a defiant terrain but with a low confidence or significance score, may elect to locally source additional sensor data from its peers in the local nest in an attempt to rule out or rule in the terrain deviation. In other words, the UAV 105 may solicit additional relevant sensor data that could be used to rule the determination of the deviant terrain as a false positive. In this scenario, the given UAV 105 or the peer UAVs may send follow-on terrain deviation messages to backend management system 215. Alternatively, low confidence and/or significance scores may result in a delay of issuing terrain deviation message 220 while additional sensor data from peer UAVs 105 may be gathered and a final deviation decision is made by terrain detection module 205 of one of UAVs 105 based on the additional sensor data.

Turning to FIG. 4B (via offpage reference 445), process 400 continues to a process block 450. In process block 450, UAV 105 continues to buffer the sensor data associated with the deviant terrain for the deviant terrain storage time. As mentioned, this storage time may be longer than typical storage times for mission logs that do not include assertion of a deviant terrain flag. This extended time period provides backend management system 215 opportunity to receive terrain deviation messages 220 from other UAVs 105 that recently passed, or are scheduled to pass, in the vicinity of the deviant terrain. Alternatively, the extended period provides extra time for backend management system 215 to solicit mission logs and/or sensor data of other UAVs 105 that recently flew routes passing near the alleged deviant terrain. In some embodiments, if terrain deviation message 220 includes a high significance score, then backend management system 215 may immediately issue a temporary no fly zone around the deviant terrain until after backend terrain model 225 has been reconstructed.

In a decision block 455, backend management system 215 makes a determination based upon the terrain deviation message 220 (and potentially other terrain deviation messages that may have been received from other UAVs), to solicit sensor data from UAV 105. This is a determination that the identified terrain deviation is deemed significant enough to dedicate bandwidth resources to retrieve the necessary sensor data, including aerial images 307, and reconstruct backend terrain model 225. Accordingly, in process block 460, backend management system 215 issues the request. This request may be a one-to-one request just to the UAV 105 that transmitted terrain deviation message 220, or a one-to-many request to many UAVs 105 believed to have relevant sensor data as a sort of crowdsourcing of additional sensor data across the fleet. In response to the request, one or more UAVs 105 upload relevant senor data including aerial images 307 (process block 465). Once all available mission logs and sensor data are uploaded over network 222, the relevant portion of backend terrain model 225 is reconstructed (process 470). After reconstruction, the updated backend terrain model 225 may be redeployed as needed to the fleet as a revised local terrain model 210.

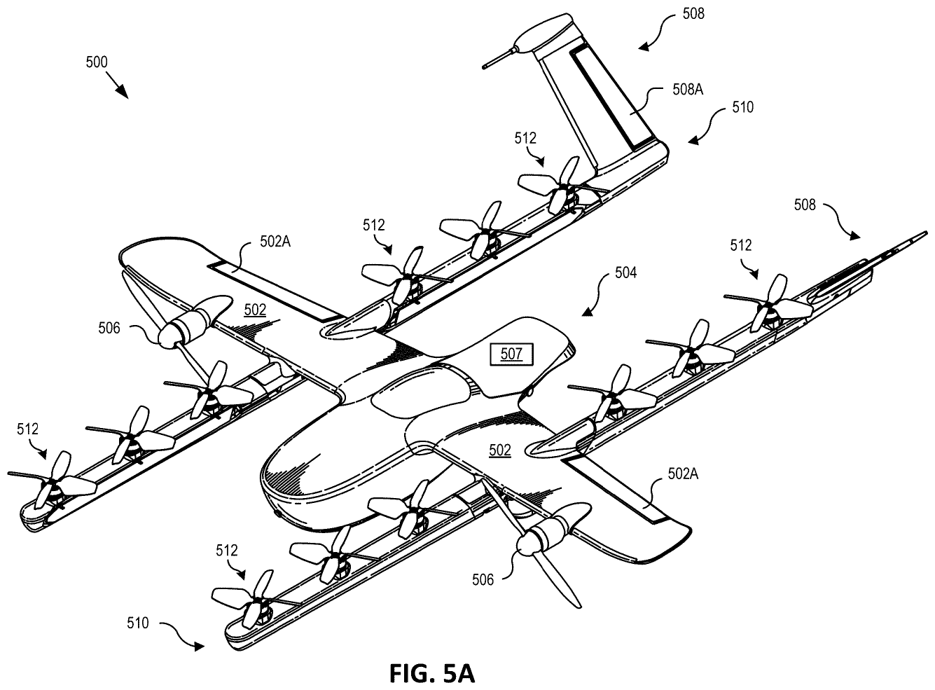

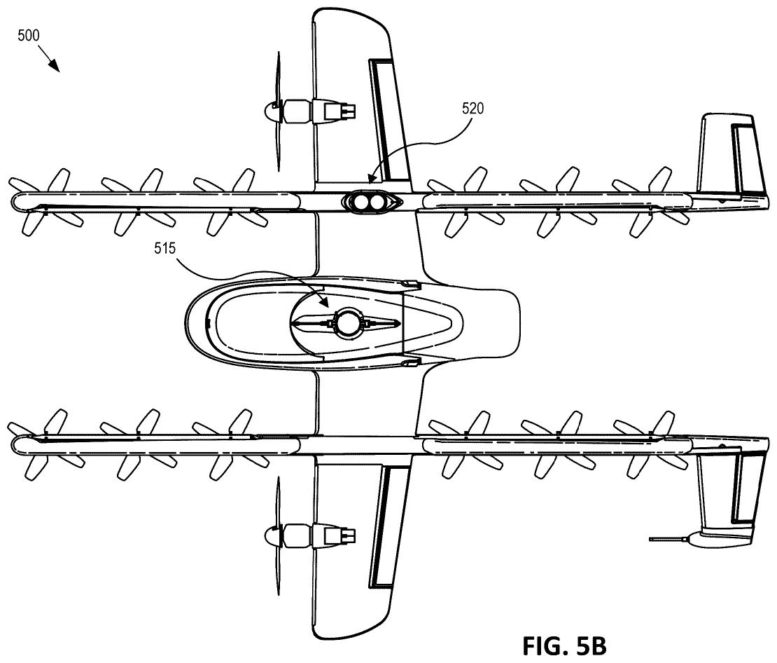

FIGS. 5A and 5B illustrate a UAV 500 that is well suited for delivery of packages, in accordance with an embodiment of the disclosure. FIG. 5A is a topside perspective view illustration of UAV 500 while FIG. 5B is a bottom side plan view illustration of the same. UAV 500 is one possible implementation of UAVs 105 illustrated in FIG. 1, although other types of UAVs may be implemented for a UAV delivery service as well.

The illustrated embodiment of UAV 500 is a vertical takeoff and landing (VTOL) UAV that includes separate propulsion units 506 and 512 for providing horizontal and vertical propulsion, respectively. UAV 500 is a fixed-wing aerial vehicle, which as the name implies, has a wing assembly 502 that can generate lift based on the wing shape and the vehicle's forward airspeed when propelled horizontally by propulsion units 506. The illustrated embodiment of UAV 500 has an airframe that includes a fuselage 504 and wing assembly 502. In one embodiment, fuselage 504 is modular and includes a battery module, an avionics module, and a mission payload module. These modules are secured together to form the fuselage or main body.

The battery module (e.g., fore portion of fuselage 504) includes a cavity for housing one or more batteries for powering UAV 500. The avionics module (e.g., aft portion of fuselage 504) houses flight control circuitry of UAV 500, which may include a processor and memory, communication electronics and antennas (e.g., cellular transceiver, wifi transceiver, etc.), and various sensors (e.g., GNSS sensor, an inertial measurement unit, a magnetic compass, a radio frequency identifier reader, etc.). Collectively, these functional electronic subsystems for controlling UAV 500, communicating, and sensing the environment may be referred to as a control system 507. Control system 507 may incorporate many of the functional components of system 300 described in connection with FIG. 3. The mission payload module (e.g., middle portion of fuselage 504) houses equipment associated with a mission of UAV 500. For example, the mission payload module may include a payload actuator 515 (see FIG. 5B) for holding and releasing an externally attached payload (e.g., package for delivery). In some embodiments, the mission payload module may include camera/sensor equipment (e.g., camera, lenses, radar, lidar, pollution monitoring sensors, weather monitoring sensors, scanners, etc.). In FIG. 5B, an onboard camera 520 (e.g., onboard camera system 305) is mounted to the underside of UAV 500 to support a computer vision system (e.g., stereoscopic machine vision) for visual triangulation and navigation as well as operate as an optical code scanner for reading visual codes affixed to packages. These visual codes may be associated with or otherwise match to delivery missions and provide the UAV with a handle for accessing destination, delivery, and package validation information. Of course, onboard camera 520 may alternatively be integrated within fuselage 504.

As illustrated, UAV 500 includes horizontal propulsion units 506 positioned on wing assembly 502 for propelling UAV 500 horizontally. UAV 500 further includes two boom assemblies 510 that secure to wing assembly 502. Vertical propulsion units 512 are mounted to boom assemblies 510. Vertical propulsion units 512 providing vertical propulsion. Vertical propulsion units 512 may be used during a hover mode where UAV 500 is descending (e.g., to a delivery location), ascending (e.g., at initial launch or following a delivery), or maintaining a constant altitude. Stabilizers 508 (or tails) may be included with UAV 500 to control pitch and stabilize the aerial vehicle's yaw (left or right turns) during cruise. In some embodiments, during cruise mode vertical propulsion units 512 are disabled or powered low and during hover mode horizontal propulsion units 506 are disabled or powered low.

During flight, UAV 500 may control the direction and/or speed of its movement by controlling its pitch, roll, yaw, and/or altitude. Thrust from horizontal propulsion units 506 is used to control air speed. For example, the stabilizers 508 may include one or more rudders 508a for controlling the aerial vehicle's yaw, and wing assembly 502 may include elevators for controlling the aerial vehicle's pitch and/or ailerons 502a for controlling the aerial vehicle's roll. While the techniques described herein are particularly well-suited for VTOLs providing an aerial delivery service, it should be appreciated that the techniques described herein are generally applicable to a variety of aircraft types (not limited to VTOLs) providing a variety of services or serving a variety of functions beyond package deliveries.

Many variations on the illustrated fixed-wing aerial vehicle are possible. For instance, aerial vehicles with more wings (e.g., an “x-wing” configuration with four wings), are also possible. Although FIGS. 5A and 5B illustrate one wing assembly 502, two boom assemblies 510, two horizontal propulsion units 506, and six vertical propulsion units 512 per boom assembly 510, it should be appreciated that other variants of UAV 500 may be implemented with more or less of these components.

It should be understood that references herein to an “unmanned” aerial vehicle or UAV can apply equally to autonomous and semi-autonomous aerial vehicles. In a fully autonomous implementation, all functionality of the aerial vehicle is automated; e.g., pre-programmed or controlled via real-time computer functionality that responds to input from various sensors and/or pre-determined information. In a semi-autonomous implementation, some functions of an aerial vehicle may be controlled by a human operator, while other functions are carried out autonomously. Further, in some embodiments, a UAV may be configured to allow a remote operator to take over functions that can otherwise be controlled autonomously by the UAV. Yet further, a given type of function may be controlled remotely at one level of abstraction and performed autonomously at another level of abstraction. For example, a remote operator may control high level navigation decisions for a UAV, such as specifying that the UAV should travel from one location to another (e.g., from a warehouse in a suburban area to a delivery address in a nearby city), while the UAV's navigation system autonomously controls more fine-grained navigation decisions, such as the specific route to take between the two locations, specific flight controls to achieve the route and avoid obstacles while navigating the route, and so on.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

A tangible machine-readable storage medium includes any mechanism that provides (i.e., stores) information in a non-transitory form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A method of maintaining a backend terrain model used by a fleet of unmanned aerial vehicles (UAVs) of a UAV service supplier (USS), the method comprising:
acquiring sensor data of a terrain below a first UAV of the fleet of UAVs as the first UAV executes a mission;
analyzing the sensor data with a terrain detection module disposed on-board the first UAV to determine whether the terrain deviates from a local terrain model describing the terrain, wherein the local terrain model is stored on-board the first UAV; and
issuing, from the first UAV to a backend management system of the USS that maintains the backend terrain model, a terrain deviation message in response to a determination that the terrain deviates from the local terrain model, wherein the terrain deviation message includes an indication that a deviant terrain has been identified and location data indicating an approximate location of the deviant terrain.

2. The method of claim 1, wherein the terrain deviation message further includes a confidence score indicating a level of confidence of the terrain detection module that the terrain deviates from the local terrain model.

3. The method of claim 1, wherein the terrain deviation message further includes a significance score indicating a perceived level of importance or hazard associated with the deviant terrain.

4. The method of claim 1, wherein issuing the terrain deviation message comprises issuing the terrain deviation message when a deviation of the terrain exceeds a threshold magnitude.

5. The method of claim 4, wherein the threshold magnitude is a dynamic threshold that changes dependent upon a land use classification or an activity classification associated with the terrain.

6. The method of claim 1, wherein the sensor data comprises an aerial image and wherein analyzing the sensor data comprises at least one of a stereovision depth analysis of the aerial image, an optical flow analysis of the aerial image, a semantic segmentation analysis of the aerial image, or a light detection and ranging analysis.

7. The method of claim 1, further comprising:
storing the sensor data onboard the first UAV after issuing the terrain deviation message for a storage time that exceeds a duration of the mission; and
uploading the sensor data to the backend management system in response to a request for the sensor data from the backend management system.

8. The method of claim 7, wherein:
the storage time associated with the deviant terrain is longer than other storage times associated with a non-deviant terrain, or
the sensor data associated with the deviant terrain is stored onboard the first UAV with a greater resolution, frame rate, or fidelity than other sensor data associated with the non-deviant terrain is stored onboard the first UAV.

9. The method of claim 1, further comprising:
in response to the terrain deviation message, issuing a group request from the backend management system to other UAVs in the fleet to upload additional sensor data of the deviant terrain acquired by the other UAVs to crowdsource the additional sensor data across the fleet.

10. The method of claim 1, further comprising:
issuing a peer-to-peer request from the first UAV to other UAVs in the fleet staged at a local nest with the first UAV, the peer-to-peer request soliciting the other UAVs for additional sensor data of the deviant terrain acquired by the other UAVs during other missions.

11. The method of claim 1, further comprising:
uploading the sensor data from the first UAV to the backend management system; and
reconstructing the backend terrain model associated with the deviant terrain based at least in part on the sensor data collected by the first UAV and in response to the terrain deviation message.

12. At least one machine-readable medium having instructions stored thereon that, in response to execution, cause an unmanned aerial vehicle (UAV) service supplier (USS) to perform operations comprising:
acquiring sensor data of a terrain below a first UAV of the USS as the first UAV executes a mission;
analyzing the sensor data with a terrain detection module disposed on-board the first UAV to determine whether the terrain deviates from a local terrain model describing the terrain, wherein the local terrain model is stored on-board the first UAV; and
issuing, from the first UAV to a backend management system of the USS that maintains a backend terrain model, a terrain deviation message in response to a determination that the terrain deviates from the local terrain model, wherein the terrain deviation message includes an indication that a deviant terrain has been identified and location data indicating an approximate location of the deviant terrain.

13. The at least one machine-accessible storage medium of claim 12, wherein the terrain deviation message further includes a confidence score indicating a level of confidence of the terrain detection module that the terrain deviates from the local terrain model.

14. The at least one machine-accessible storage medium of claim 12, wherein the terrain deviation message further includes a significance score indicating a perceived level of importance or hazard associated with the deviant terrain.

15. The at least one machine-accessible storage medium of claim 12, wherein issuing the terrain deviation message comprises issuing the terrain deviation message when a deviation of the terrain exceeds a threshold magnitude.

16. The at least one machine-accessible storage medium of claim 15, wherein the threshold magnitude is a dynamic threshold that changes dependent upon a land use classification or an activity classification associated with the terrain.

17. The at least one machine-accessible storage medium of claim 12, wherein the sensor data comprises an aerial image and wherein analyzing the sensor data comprises at least one of a stereovision depth analysis of the aerial image, an optical flow analysis of the aerial image, a semantic segmentation analysis of the aerial image, or a light detection and ranging analysis.

18. The at least one machine-accessible storage medium of claim 12, wherein the operations further comprise:
storing the sensor data onboard the first UAV after issuing the terrain deviation message for a storage time that exceeds a duration of the mission; and
uploading the sensor data to the backend management system in response to a request for the sensor data from the backend management system.

19. The at least one machine-accessible storage medium of claim 18, wherein:
the storage time associated with the deviant terrain is longer than other storage times associated with a non-deviant terrain, or
the sensor data associated with the deviant terrain is stored onboard the first UAV with a greater resolution, frame rate, or fidelity than other sensor data associated with the non-deviant terrain is stored onboard the first UAV.

20. The at least one machine-accessible storage medium of claim 12, wherein the operations further comprise:
in response to the terrain deviation message, issuing a group request from the backend management system to other UAVs in the fleet to upload additional sensor data of the deviant terrain acquired by the other UAVs to crowdsource the additional sensor data across the fleet.
